(19) United States
(12) Patent Application Publication
(10) Pub. No.: US 2007/0009839 A1
(43) Pub. Date: Jan. 11, 2007

(54) Pattern forming method, film forming apparatus and pattern forming apparatus

(75) Inventor: Masahiko Harumoto, Kyoto (JP)

Correspondence Address: OSTROLENK FABER GERB & SOFFEN, 1180 AVENUE OF THE AMERICAS, NEW YORK, NY, 100368403, US

(73) Assignee: Dainippon Screen Mfg. Co., Ltd.

(21) Appl. No.: 11/476,499

(22) Filed: Jun. 28, 2006

(30) Foreign Application Priority Data
Jul. 6, 2005 (JP) 2005-197601

(51) Int. Cl. G03F 7/26

(52) U.S. Cl. 430/313; 430/331

(57) ABSTRACT

A pattern forming method for forming a predetermined pattern on a substrate includes the steps of supplying a developer to a photosensitive film coating the substrate and having a latent image of the pattern formed thereon, to form a pattern of the photosensitive film, replacing the developer with a rinsing liquid, supplying a polymer soluble in the rinsing liquid while drying the substrate, to cover an entire surface of the photosensitive film on the substrate, and removing one of the pattern of the photosensitive film and the polymer by dry etching.

### BACKGROUND OF THE INVENTION

(1) Field of the Invention

This invention relates to pattern forming methods, film forming apparatus and pattern forming apparatus for forming a predetermined pattern on substrates such as semiconductor wafers and glass substrates for liquid crystal displays (hereinafter called simply substrates).

(2) Description of the Related Art

With an increasingly refined pattern formed on substrates in recent years, photoresist film has been required to form a pattern with a high ratio of height to width (called an aspect ratio). An aspect ratio exceeding 2.5 to 3, in particular, results in a phenomenon that the pattern of the photoresist film collapses in a developing process. This is because, when a rinsing liquid dries in the developing stage, the surface tension of the rinsing liquid acts on the pattern of the photoresist film, and the pattern with the high aspect ratio is not strong enough to withstand the force applied by the surface tension.

In a first method known in the art for solving this problem, rinsing treatment is carried out by supplying a rinsing liquid containing a perfluorocarbon solvent, for example, as a solvent (low surface tension solvent) for reducing the surface tension of the rinsing liquid (as disclosed in Japanese Unexamined Patent Publication No. 2004-14844).

In a second known method, a liquid including a resin dissolvable in a rinsing liquid is mixed into the rinsing liquid. This mixture is supplied to a pattern of photoresist film to deposit the resin thereon. This reduces the surface tension, and increases the strength of the base of the pattern by allowing the resin to cure (e.g. Japanese Unexamined Patent Publication No. 1995-335519).

The above known methods have the following drawbacks.

In the first known method, although the rinsing liquid for reducing the surface tension is used, the pattern is invariably subjected to the surface tension when the rinsing liquid dries, i.e. when the liquid surface lowers toward bottoms between parts of the pattern). Thus, there is a problem that the collapse of the pattern is unavoidable.

In the second known method, although the pattern is reinforced, an etching process is carried out with the pattern used as a mask after removing the resin from the pattern. Thus, the surface tension of the etching solution can collapse the pattern. With a still higher aspect ratio, the pattern will be collapsed by the surface tension of the rinsing liquid even if the base of the pattern is reinforced with the resin.

### SUMMARY OF THE INVENTION

This invention has been made having regard to the state of the art noted above, and its object is to provide pattern forming methods, film forming apparatus and pattern forming apparatus devised to prevent a collapse of a pattern with a high aspect ratio by keeping the pattern free from surface tension.

The above object is fulfilled, according to this invention, by a pattern forming method for forming a predetermined pattern on a substrate, comprising the steps of supplying a developer to a photosensitive film coating the substrate and having a latent image of the pattern formed thereon, to form a pattern of the photosensitive film; replacing the developer with a rinsing liquid; supplying a polymer soluble in the rinsing liquid while drying the substrate, to cover an entire surface of the photosensitive film on the substrate; and removing one of the pattern of the photosensitive film and the polymer by dry etching.

According to this invention, after forming a pattern of photosensitive film by development, the developer is replaced by the rinsing liquid. While drying the substrate, the polymer supplied to the substrate to cover the entire surface of photosensitive film with the polymer. That is, spaces between parts of the pattern are filled with the polymer, without leaving gaps, before the rinsing liquid dries and surface tension acts between the parts of the pattern. Since the rinsing liquid does not apply surface tension between the parts of the pattern in time of drying, the pattern is prevented from collapsing during the developing process. Subsequently, the pattern of photosensitive film or the polymer is removed by dry etching. Therefore, no surface tension of liquid takes place also in time of etching. This prevents a collapse of even a pattern of high aspect ratio.

A pattern forming method for forming a predetermined pattern on a substrate, according to another aspect of the invention, comprises the steps of supplying a developer to a photosensitive film coating the substrate and having a latent image of the pattern formed thereon, to form a pattern of the photosensitive film; replacing the developer with a rinsing liquid, and supplying a polymer soluble in the rinsing liquid to cover an entire surface of the photosensitive film on the substrate; drying the substrate; and removing one of the pattern of the photosensitive film and the polymer by dry etching.

According to this invention, after forming a pattern of photosensitive film by development, the developer is replaced by the rinsing liquid. The substrate is dried after the polymer is supplied to the rinsing liquid to cover the entire surface of photosensitive film with the polymer. That is, by filling the spaces between parts of the pattern with the polymer without leaving gaps, the rinsing liquid does not apply surface tension between the parts of the pattern in time of drying, thereby preventing the pattern from collapsing during the developing process. Subsequently, the pattern of photosensitive film or the polymer is removed by dry etching. Therefore, no surface tension of liquid takes place also in time of etching. This prevents a collapse of even a pattern of high aspect ratio.

The polymer may have a lower etching rate in the dry etching than the photosensitive film.

A pattern of the polymer can be formed by removing only the photosensitive film by etching. Since the final pattern formed on the substrate is reverse to the normal pattern in this case, an exposure mask of reversed pattern should be prepared in advance. Instead of using the exposure mask of reversed pattern, a photosensitive film having an inverse characteristic may be used. That is, where the pattern of the exposure mask has been designed for a positive type photosensitive film, for example, the photosensitive film may be the negative type instead.

In a further aspect of the invention, a film forming apparatus for forming a film on a substrate comprises a spin support device for spinnably supporting the substrate; a developer supply device for supplying a developer from above the spin support device; a rinse supply device for supplying a rinsing liquid from above the spin support device; a polymer supply device for supplying a polymer soluble in the rinse liquid from above the spin support device; and a control device for supplying the developer from the developer supply device to the substrate supported by the spin support device and coated with a photosensitive film having a latent image of the pattern formed thereon, supplying the rinsing liquid from the rinse supply device to replace the developer, supplying the polymer from the polymer supply device, while spinning and drying the substrate with the spin support device, to cover an entire surface of the photosensitive film on the substrate, and forming on the substrate a film from which one of the pattern of the photosensitive film and the polymer is removable by dry etching.

With this apparatus, the control device supplies the developer from the developer supply device to the substrate supported by the spin support device, to form a pattern of photosensitive film. Thereafter the rinsing liquid is supplied from the rinse supply device to replace the developer. While drying the substrate with the spin support device, the polymer is supplied from the polymer supply device to cover the entire surface of the photosensitive film. That is, before the rinsing liquid dries to apply its surface tension between parts of the pattern, the control device fills the polymer between the parts of the pattern without leaving gaps. Since the rinsing liquid does not apply surface tension between the parts of the pattern in time of drying, the pattern is prevented from collapsing during the developing process. Subsequently, the pattern of the photosensitive film or the polymer is removed by dry etching. It is thus possible to form on the substrate the film for forming a final pattern of high aspect ratio.

In a still further aspect of the invention, a film forming apparatus for forming a film on a substrate comprises a spin support device for spinnably supporting the substrate; a developer supply device for supplying a developer from above the spin support device; a rinse supply device for supplying a rinsing liquid from above the spin support device; a polymer supply device for supplying a polymer soluble in the rinse liquid from above the spin support device; and a control device for supplying the developer from the developer supply device to the substrate supported by the spin support device and coated with a photosensitive film having a latent image of the pattern formed thereon, supplying the rinsing liquid from the rinse supply device to replace the developer, supplying the polymer from the polymer supply device to cover an entire surface of the photosensitive film on the substrate, spinning and drying the substrate with the spin support device, and forming on the substrate a film from which one of the pattern of the photosensitive film and the polymer is removable by dry etching.

With this apparatus, the control device supplies the developer from the developer supply device to the substrate supported by the spin support device, to form a pattern of photosensitive film. Thereafter the rinsing liquid is supplied from the rinse supply device to replace the developer, and the polymer is supplied from the polymer supply device to cover the entire surface of the photosensitive film. Then, the controller causes the substrate to dry. That is, by filling the spaces between parts of the pattern with the polymer without leaving gaps, the rinsing liquid does not apply surface tension between the parts of the pattern in time of drying, thereby preventing the pattern from collapsing during the developing process. Subsequently, the pattern of photosensitive film or the polymer is removed by dry etching. It is thus possible to form on the substrate the film for forming a final pattern of high aspect ratio.

In a different aspect of the invention, a pattern forming apparatus for forming a pattern on a substrate comprises a spin support device for spinnably supporting the substrate; a developer supply device for supplying a developer from above the spin support device; a rinse supply device for supplying a rinsing liquid from above the spin support device; a polymer supply device for supplying a polymer soluble in the rinse liquid from above the spin support device; a dry etching device for ashing one of the film and the polymer; and a control device for supplying the developer from the developer supply device to the substrate supported by the spin support device and coated with a photosensitive film having a latent image of the pattern formed thereon, supplying the rinsing liquid from the rinse supply device to replace the developer, supplying the polymer from the polymer supply device, while spinning and drying the substrate with the spin support device, to cover an entire surface of the photosensitive film on the substrate, and operating the dry etching device for ashing one of the pattern of the photosensitive film and the polymer.

With this apparatus, the control device supplies the developer from the developer supply device to the substrate supported by the spin support device, to form a pattern of photosensitive film. Thereafter the rinsing liquid is supplied from the rinse supply device to replace the developer. While drying the substrate with the spin support device, the polymer is supplied from the polymer supply device to cover the entire surface of the photosensitive film. Subsequently, the control device operates the dry etching device for ashing the pattern of the photosensitive film or the polymer. That is, before the rinsing liquid dries to apply its surface tension between parts of the pattern, the control device fills the polymer between the parts of the pattern without leaving gaps. Since the rinsing liquid does not apply surface tension between the parts of the pattern in time of drying, the pattern is prevented from collapsing during the developing process. Subsequently, the pattern of the photosensitive film or the polymer is removed by the dry etching device. Therefore, no surface tension of liquid takes place also in time of etching. This prevents a collapse of even a pattern of high aspect ratio.

In a still further aspect of the invention, a pattern forming apparatus for forming a predetermined pattern on a substrate comprises a spin support device for spinnably supporting the substrate; a developer supply device for supplying a developer from above the spin support device; a rinse supply device for supplying a rinsing liquid from above the spin support device; a polymer supply device for supplying a polymer soluble in the rinse liquid from above the spin support device; a dry etching device for ashing one of the film and the polymer; and a control device for supplying the developer from the developer supply device to the substrate supported by the spin support device and coated with a photosensitive film having a latent image of the pattern formed thereon, supplying the rinsing liquid from the rinse supply device to replace the developer, supplying the polymer from the polymer supply device to cover an entire surface of the photosensitive film on the substrate, spinning and drying the substrate with the spin support device, and operating the dry etching device for ashing one of the pattern of the photosensitive film and the polymer.

With this apparatus, the control device supplies the developer from the developer supply device to the substrate supported by the spin support device, to form a pattern of photosensitive film. Thereafter the rinsing liquid is supplied from the rinse supply device to replace the developer, and the polymer is supplied from the polymer supply device to cover the entire surface of the photosensitive film. Then, the substrate is dried. Subsequently, the control device operates the dry etching device for ashing the pattern of the photosensitive film or the polymer. That is, before the rinsing liquid dries to apply its surface tension between parts of the pattern, the control device fills the polymer between the parts of the pattern without leaving gaps. Since the rinsing liquid does not apply surface tension between the parts of the pattern in time of drying, the pattern is prevented from collapsing during the developing process. Subsequently, the pattern of the photosensitive film or the polymer is removed by the dry etching device. Therefore, no surface tension of liquid takes place also in time of etching. This prevents a collapse of even a pattern of high aspect ratio.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIGS. 1A-1D are views in vertical section of a substrate showing a process of treating the substrate by a pattern forming method in Embodiment 1;

FIGS. 2A-2C are views in vertical section of the substrate showing a process of treating the substrate by the pattern forming method in Embodiment 1;

FIGS. 3A and 3B are views in vertical section of the substrate showing a process of treating the substrate by the pattern forming method in Embodiment 1;

FIGS. 4A-4D are views in vertical section of a substrate showing a process of treating the substrate by a pattern forming method in Embodiment 2;

FIGS. 5A-5D are views in vertical section of the substrate showing a process of treating the substrate by the pattern forming method in Embodiment 2;

FIG. 6 is a block diagram showing a film forming apparatus according to the invention; and

FIG. 7 is a view showing a dry etching apparatus according to the invention.

### DESCRIPTION OF THE PREFERRED EMBODIMENTS

### Embodiment 1

Embodiment 1 of this invention will be described hereinafter with reference to the drawings.

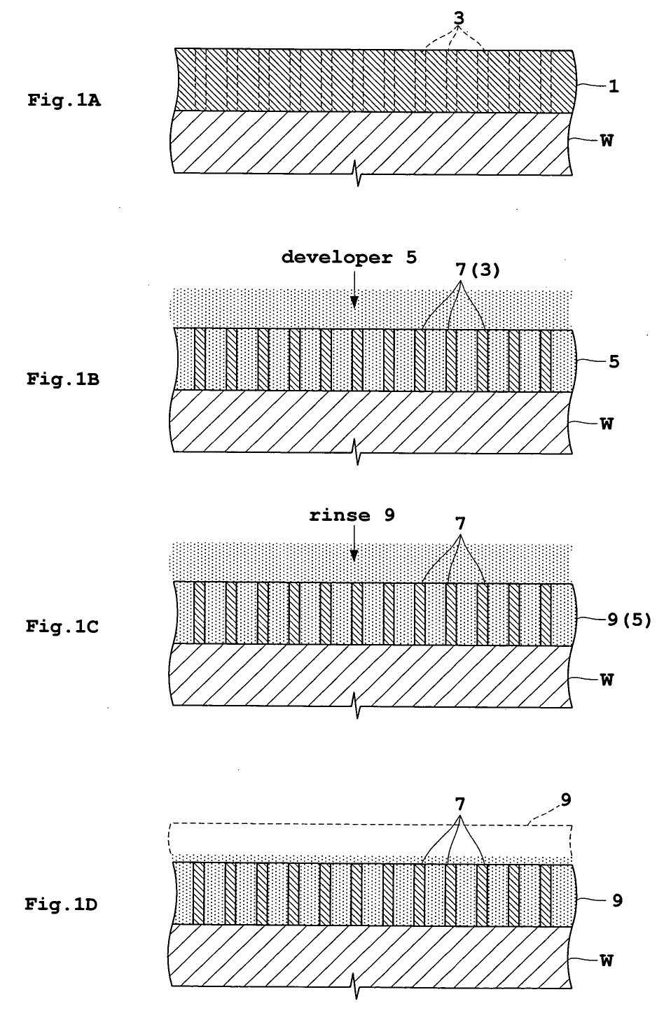

FIGS. 1 through 3 are views in vertical section of a substrate showing a process of treating the substrate by a pattern forming method in Embodiment 1.

A substrate or wafer W has a photosensitive film 1 formed on an upper surface thereof. The photosensitive film 1 is exposed through a mask having a predetermined pattern to form a latent image 3 corresponding to the predetermined pattern (FIG. 1A). The photosensitive film 1 is also called photoresist film, and is formed, for example, by using a spin coating apparatus (also called a spin coater).

When a developer 5 is supplied to the photosensitive film 1 on the wafer W and this state is maintained for a predetermined time, exposed portions of the photosensitive film 1 are dissolved by the developer, for example, and the latent image 3 forms a pattern 7 (FIG. 1B). In order to restrain a collapse of the pattern by liquid currents, the developing process is performed in what is called puddle development for holding the developer 5 in puddle form without spinning the wafer W.

The supply of developer 5 is stopped, and subsequently a rinsing liquid 9 is supplied to stop the developing process (FIG. 1C). The rinsing liquid 9 may be deionized water, for example. However, depending on the type of photosensitive film 1, a rinsing liquid containing a solvent is used.

After performing the rinsing process with the rinsing liquid 9 for a predetermined time, the supply of rinsing liquid 9 is stopped, and the wafer W is dried to remove the rinsing liquid 9 covering the pattern 7 (FIG. 1D). In order to restrain a collapse of the pattern 7, a drying process by spin-scattering, preferably, is carried out at low spinning speed.

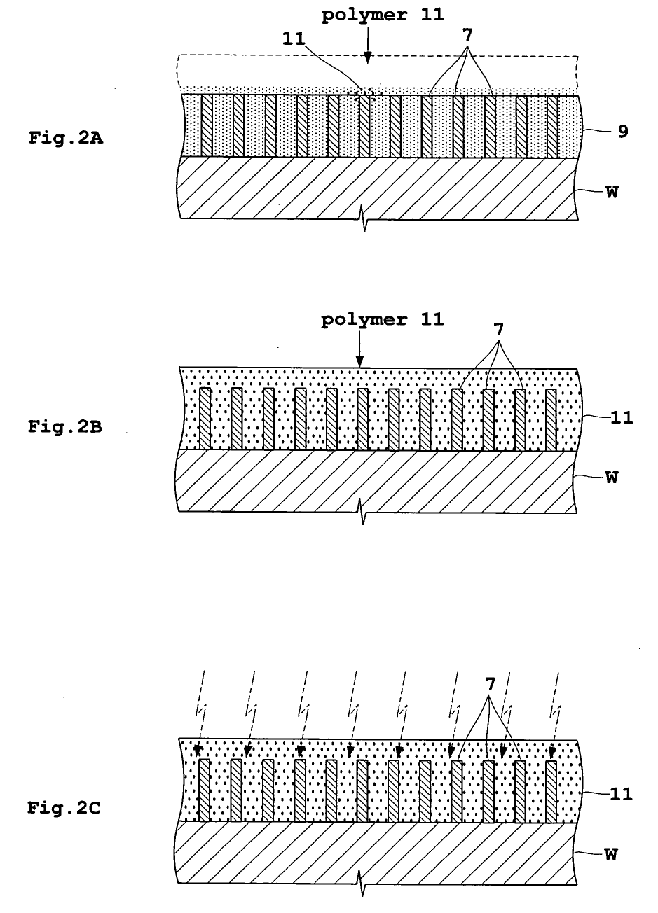

While the wafer W is dried as described above, a polymer 11 is supplied in a state of the rinsing liquid 9 covering the pattern 7 (FIG. 2A). The polymer 11 covers spaces between parts of the pattern 7 as well as upper parts of the pattern 7 (FIG. 2B).

Since the polymer 11 is supplied in the state of the rinsing liquid 9 covering the pattern 7, the polymer 11 used is soluble in the rinsing liquid 9 to secure a sufficient affinity for each other. Specifically, a preferred polymer is based on a siloxane, a silicic acid having the Si—O skeleton, or a glass resin. For the above photosensitive film 1 and polymer 11, materials of different etching rates are selected since a dry etching process is carried out as described hereinafter. In this embodiment, for example, the photosensitive film 1 (pattern 7) has a high etching rate (a large etching quantity) in the dry etching process.

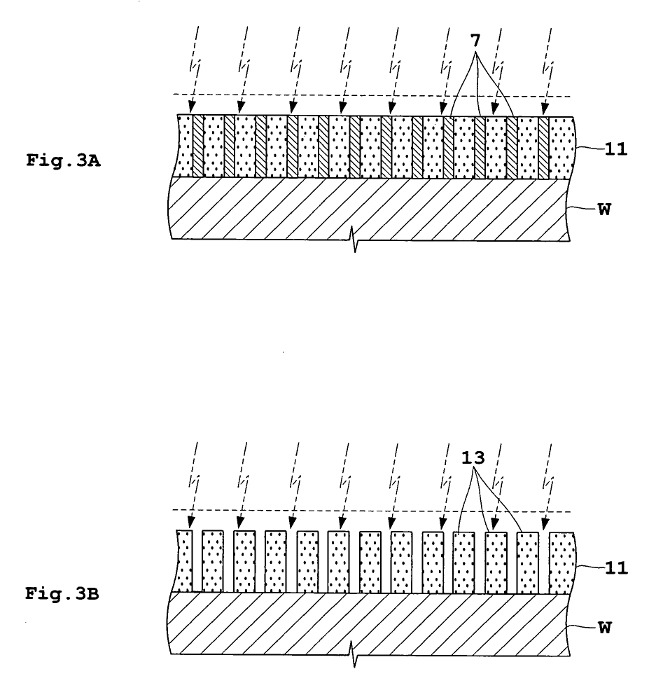

After the polymer 11 covering the pattern 7 is dried, the dry etching process is performed (FIG. 2C). Specifically, an ashing process is carried out using plasma. In an early stage of the ashing process, only the polymer 11 covering the entire surface of the wafer W is ashed gradually (FIG. 3A). Then, after the pattern 7 is exposed, the pattern 7 is ashed markedly faster than the polymer 11 (FIG. 3B). As a result, traces of the pattern 7 are formed, and a final pattern 13 reverse to the pattern 7 is formed by the polymer 11. Since the final pattern 13 formed on the wafer W is reverse to the normal pattern in this case, an exposure mask of reversed pattern should be prepared in advance.

However, this does not apply where the photosensitive film has an inverse characteristic. That is, where the pattern of the exposure mask has been designed for a positive type photosensitive film, for example, the photosensitive film may be the negative type instead of using an exposure mask of reversed pattern.

After forming the pattern 7 of photosensitive film 1 by development as described above, the developer 5 is replaced by the rinsing liquid 9. While drying the wafer W, the polymer 11 is supplied to the wafer W to cover the entire surface of photosensitive film 1 with the polymer 11. That is, spaces between parts of the pattern 7 are filled with the polymer 11, without leaving gaps, before the rinsing liquid 9 dries and surface tension acts between the parts of the pattern 7. Since the rinsing liquid 9 does not apply surface tension between the parts of the pattern 7 in time of drying, the pattern 7 is prevented from collapsing during the developing process. Subsequently, the pattern 7 of photosensitive film 1 is removed by dry etching. Therefore, no surface tension of liquid takes place also in time of etching. Even if the final pattern 13 is generated from the pattern 7 of high aspect ratio, its collapse is prevented.

### Embodiment 2

Embodiment 2 of this invention will be described hereinafter with reference to the drawings.

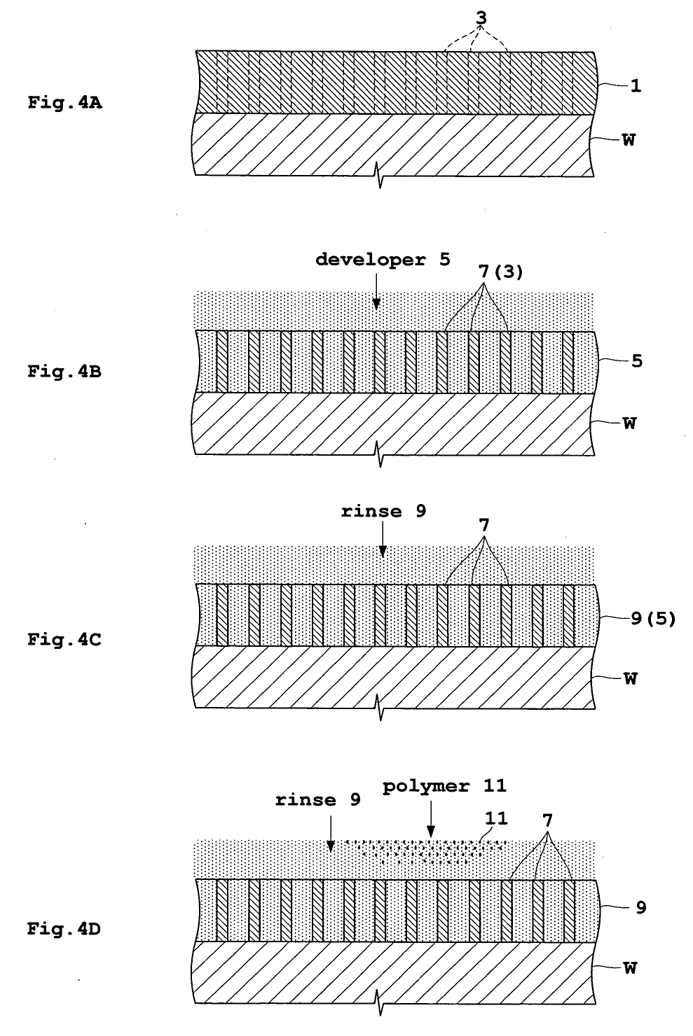

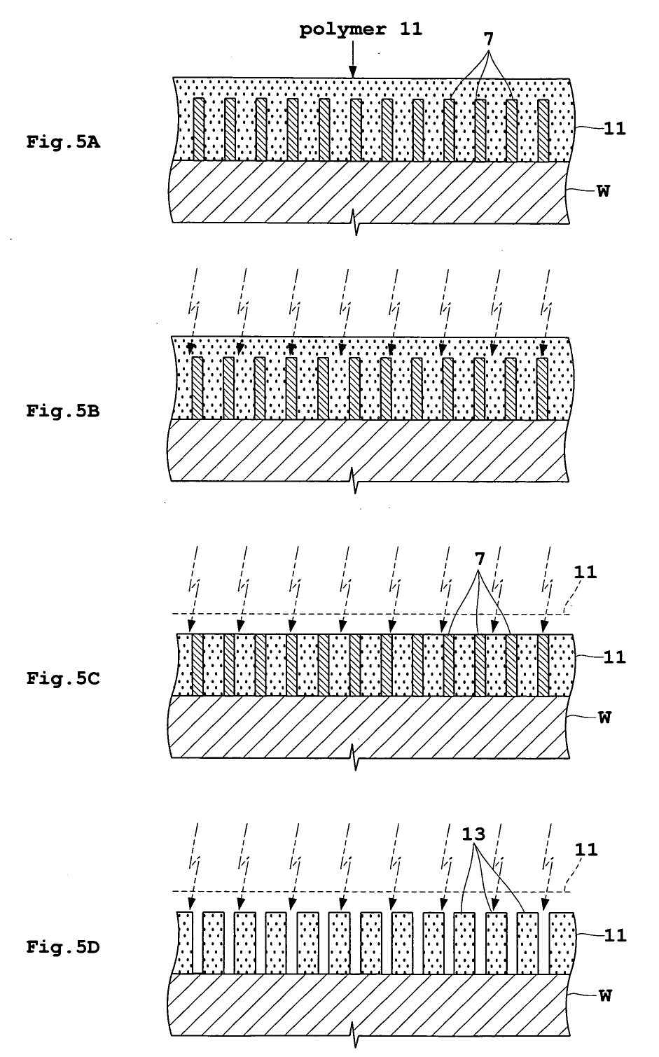

FIGS. 4 and 5 are views in vertical section of a substrate showing a process of treating the substrate by a pattern forming method in Embodiment 2. This embodiment is different from Embodiment 1 described above, in timing of supplying polymer 11.

A wafer W has a photosensitive film 1 formed thereon, and a latent image 3 corresponding to a predetermined pattern is formed on the photosensitive film 1 (FIG. 4A). Then, a developer 5 is supplied to form a pattern 7 (FIG. 4B). The developer 5 is replaced by a rinsing liquid 9 (FIG. 4C).

While maintaining the supply of rinsing liquid 9 for replacement, a polymer 11 is supplied (FIG. 4D). After stopping the supply of rinsing liquid 9, the supply of polymer 11 is stopped. As a result, the pattern 7 is covered by the polymer 11 (FIG. 5A).

After drying the polymer 11 covering the pattern 7, a dry etching process is performed (FIGS. 5B-5D). As a result, traces of the pattern 7 are formed, and a final pattern 13 reverse to the pattern 7 is formed by the polymer 11.

After forming the pattern 7 of photosensitive film 1 by development as described above, the developer 5 is replaced by the rinsing liquid 9. The wafer W is dried after the polymer 11 is supplied to the rinsing liquid 9 to cover the entire surface of photosensitive film 1 with the polymer 11. That is, by filling the spaces between parts of the pattern 7 with the polymer 11 without leaving gaps, the rinsing liquid 9 does not apply surface tension between the parts of the pattern 7 in time of drying, thereby preventing the pattern 7 from collapsing during the developing process. Subsequently, the pattern 7 of photosensitive film 1 is removed by dry etching. Therefore, no surface tension of liquid takes place also in time of etching. Even if the final pattern 13 is generated from the pattern 7 of high aspect ratio, its collapse is prevented.

### Embodiment 3

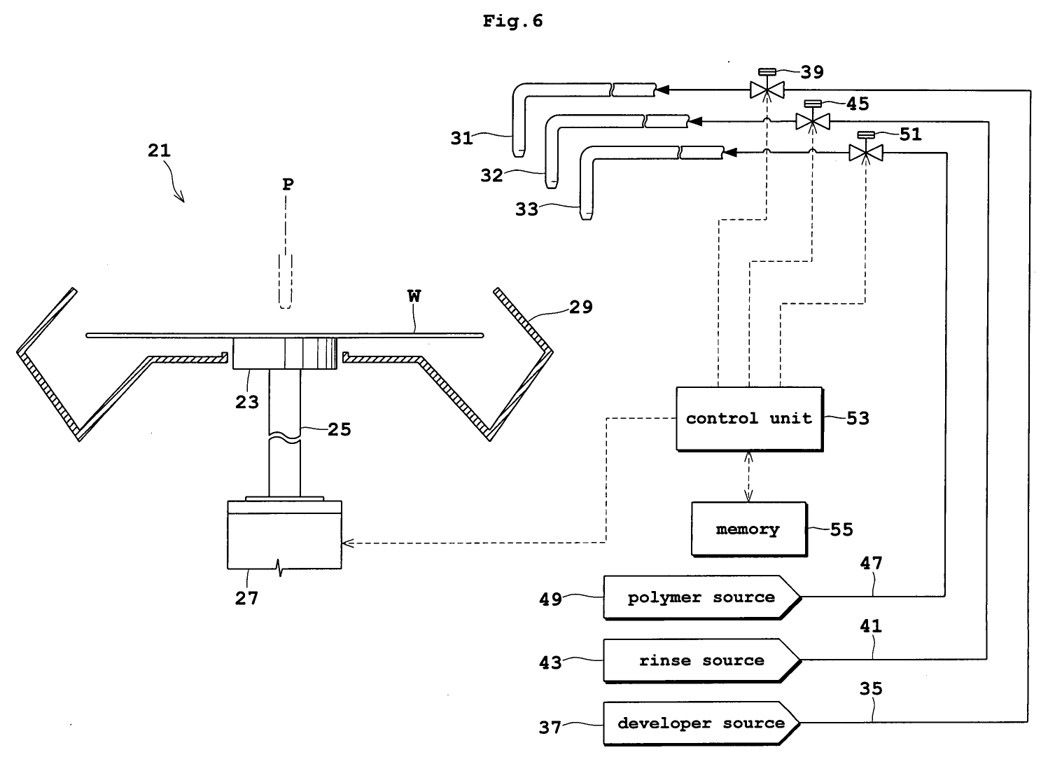

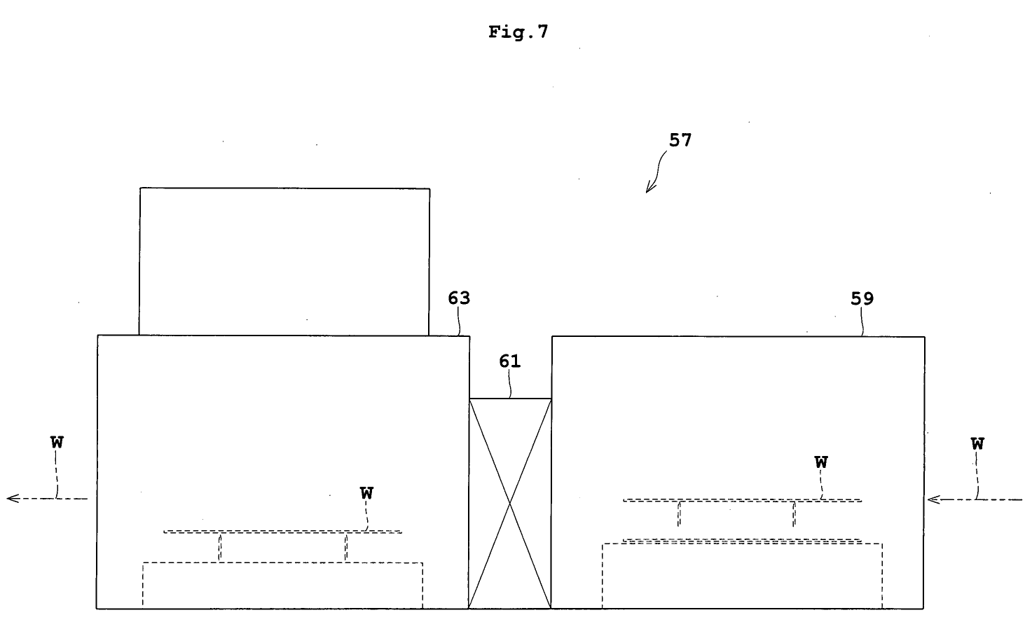

Next, an apparatus suited for carrying out the above Embodiments 1 and 2 will be described as Embodiment 3 with reference to the drawings. FIG. 6 is a block diagram showing a film forming apparatus according to the invention. FIG. 7 is a view showing a dry etching apparatus according to the invention.

A film forming apparatus 21 forms a pattern 7 of coating film 1 on the upper surface of wafer W, and then forms a film of polymer 11 covering the pattern 7. A spin chuck 23 corresponding to the spin support device in this invention holds the wafer W in horizontal posture by sucking a center region on the lower surface of the wafer W. A rotary shaft 25 is connected to a lower part of the spin chuck 23, and is interlocked at a lower end thereof to a rotary shaft of a motor 27. The spin chuck 23 is surrounded by a vertically movable scatter preventive cup 29. The scatter preventive cup 29 has a function for downwardly guiding and collecting treating solutions such as the developer scattering from outer edges of the wafer W to the ambient.

A first nozzle 31, a second nozzle 32 and a third nozzle 33 are arranged laterally of the scatter preventive cup 29 to be movable between a “supply position” adjacent a spin center P, shown in two-dot chain lines in FIG. 6, and a “standby position” shown in solid lines in FIG. 6. The first nozzle 31 corresponds to the developer supply device in this invention. The second nozzle 32 corresponds to the rinse supply device in this invention. The third nozzle 33 corresponds to the polymer supply device in this invention.

The first nozzle 31 has a developer source 37 connected thereto through piping 35. The piping 35 has a switch valve 39 mounted thereon for controlling supply and stopping of a developer. The second nozzle 32 has a rinse source 43 connected thereto through piping 41. The piping 41 has a switch valve 45 mounted thereon for controlling supply of a rinsing liquid. The third nozzle 32 has a polymer source 49 connected thereto through piping 47. The piping 47 has a switch valve 51 mounted thereon for controlling supply of a polymer.

The operation of the above motor 27 and switch valves 39, 45 and 51, the movement of the first nozzle 31, second nozzle 32 and third nozzle 33 are controlled by a controller 53 corresponding to the control device in this invention. Operating timing of each component is controlled by referring to a memory 55 storing a recipe specifying a procedure.

FIG. 7 refers.

A dry etching apparatus 57 includes a baking unit 59, a transport unit 61 and a plasma asher 63 arranged in order. The baking unit 59 serves for heat-treating the wafer W at a high temperature in order to remove moisture of the rinsing liquid contained in the final pattern 13 of polymer 11 formed on the wafer W. The treating temperature is about 100 to 140° C., for example. The plasma asher 63 corresponds to the dry etching device in this invention.

The transport unit 61 transports the wafer W heat-treated in the baking unit 59 to the plasma asher 63.

The plasma asher 63 performs a process for ashing the pattern 7 of photosensitive film 1 in order to form the final pattern 13 as described hereinbefore. After the process by the plasma asher 63, the final pattern 13 is formed on the wafer W. In the illustrated example, the plasma asher 63 is the single wafer type for treating one wafer W in horizontal posture at a time. The plasma asher 63 may be the batch type for simultaneously treating a plurality of wafers W received from the transport unit 61, in vertical posture.

Next, the process by the above apparatus will be described with reference to FIGS. 1 through 3. The controller 53 of the film forming apparatus 21 accesses the memory 55 and refers to a recipe for Embodiment 1 described hereinbefore. In order to supply the developer 5, the controller 53 moves the first nozzle 31 to the supply position, and supplies the developer 5 in a predetermined quantity to the wafer W to form a puddle thereon. When a predetermined time passes to complete the developing process, in order to supply the rinsing liquid 9 next, the controller 53 moves the second nozzle 32 to the supply position, and supplies the rinsing liquid 9 while rotating the motor 27 at low speed, to replace the developer 5 with the rinsing liquid 9. When the rinsing treatment of predetermined time is completed, the controller 53 stops the supply of rinsing liquid 9, retreats the second nozzle 32, and moves the third nozzle 33 to the supply position. The polymer 11 is supplied after a predetermined time and before the pattern 7 is exposed from the rinsing liquid 9. After a supply time during which the polymer 11 covers the pattern 7 and the entire surface of the wafer W, the supply of polymer 11 is stopped and the rotational frequency of motor 27 is increased to scatter surplus part of the polymer 11 to dry the wafer W.

Thus, after supplying the developer 5 to form the pattern 7 of photosensitive film 1, the control unit 53 supplies the rinsing liquid 9 to replace the developer 5, and supplies the polymer 11 to cover the entire surface of photosensitive film 1, while drying the wafer W. That is, before the rinsing liquid 9 dries to apply its surface tension between parts of the pattern 7, the polymer 11 is filled between the parts of the pattern 7 without leaving gaps. Since the rinsing liquid 9 does not apply surface tension between the parts of the pattern 7 in time of drying, the pattern 7 is prevented from collapsing during the developing process. Subsequently, the pattern 7 of photosensitive film 1 is removed by dry etching. It is thus possible to form on the wafer W the film for forming the final pattern 13 of high aspect ratio.

Next, the wafer W covered by the polymer 11 is loaded into the baking unit 59 of the dry etching apparatus 57 to remove the moisture contained in the polymer 11 by heat treatment therein. Then, the wafer W is transported to the plasma asher 63 by the transport unit 61. Here, part of the polymer 11 and pattern 7 are ashed, to form the final pattern 13 on the wafer W.

When the controller 53 of the film forming apparatus 21 accesses the memory 55 and refers to a recipe for Embodiment 2 described hereinbefore, the same process takes place except the difference in timing of supplying the polymer 11 as particularly described in Embodiment 2 above.

This invention is not limited to the foregoing embodiments, but may be modified as follows:

(1) In Embodiments 1 and 2 described above, the pattern 7 of photosensitive film 1 is removed in the dry etching process. Instead, the polymer 11 may be removed. This allows use of an ordinary exposure mask.

(2) In Embodiment 3 described above, the film forming apparatus 21 and dry etching apparatus 57 are constructed separately. These apparatus may be integrated into a pattern forming apparatus. This may promote processing efficiency.

(3) The plasma asher 63 in Embodiment 3 may be replaced, for example, by a reactive ion etching system or reactive sputter etching system.

(4) In Embodiment 3 described above, the film forming apparatus 21 employs the spin chuck 23 of the suction type as the spin support device. It is possible to employ, instead, what is called a mechanical chuck having a plurality of support pins erected in peripheral positions of a base for contacting and supporting edges of the wafer W.

This invention may be embodied in other specific forms without departing from the spirit or essential attributes thereof and, accordingly, reference should be made to the appended claims, rather than to the foregoing specification, as indicating the scope of the invention.

What is claimed is:

1. A pattern forming method for forming a predetermined pattern on a substrate, comprising the steps of:
supplying a developer to a photosensitive film coating the substrate and having a latent image of the pattern formed thereon, to form a pattern of the photosensitive film;
replacing the developer with a rinsing liquid;
supplying a polymer soluble in the rinsing liquid while drying the substrate, to cover an entire surface of the photosensitive film on the substrate; and
removing one of the pattern of the photosensitive film and the polymer by dry etching.

2. A pattern forming method for forming a predetermined pattern on a substrate, comprising the steps of:
supplying a developer to a photosensitive film coating the substrate and having a latent image of the pattern formed thereon, to form a pattern of the photosensitive film;
replacing the developer with a rinsing liquid, and supplying a polymer soluble in the rinsing liquid to cover an entire surface of the photosensitive film on the substrate;
drying the substrate; and
removing one of the pattern of the photosensitive film and the polymer by dry etching.

3. A method as defined in claim 1, wherein said polymer has a lower etching rate in the dry etching than said photosensitive film.

4. A method as defined in claim 2, herein said polymer has a lower etching rate in the dry etching than said photosensitive film.

5. A method as defined in claim 1, wherein said polymer is based on one of a siloxane, a silicic acid having a Si—O skeleton, and a glass resin.

6. A method as defined in claim 2, wherein said polymer is based on one of a siloxane, a silicic acid having a Si—O skeleton, and a glass resin.

7. A method as defined in claim 3, wherein said polymer is based on one of a siloxane, a silicic acid having a Si—O skeleton, and a glass resin.

8. A method as defined in claim 4, wherein said polymer is based on one of a siloxane, a silicic acid having a Si—O skeleton, and a glass resin.

9. A film forming apparatus for forming a film on a substrate, comprising:
a spin support device for spinnably supporting the substrate;
a developer supply device for supplying a developer from above said spin support device;
a rinse supply device for supplying a rinsing liquid from above said spin support device;
a polymer supply device for supplying a polymer soluble in the rinse liquid from above said spin support device; and
a control device for supplying the developer from said developer supply device to the substrate supported by said spin support device and coated with a photosensitive film having a latent image of the pattern formed thereon, supplying the rinsing liquid from said rinse supply device to replace the developer, supplying the polymer from said polymer supply device, while spinning and drying the substrate with said spin support device, to cover an entire surface of the photosensitive film on the substrate, and forming on the substrate a film from which one of the pattern of the photosensitive film and the polymer is removable by dry etching.

10. A film forming apparatus for forming a film on a substrate, comprising:
a spin support device for spinnably supporting the substrate;
a developer supply device for supplying a developer from above said spin support device;
a rinse supply device for supplying a rinsing liquid from above said spin support device;
a polymer supply device for supplying a polymer soluble in the rinse liquid from above said spin support device; and
a control device for supplying the developer from said developer supply device to the substrate supported by said spin support device and coated with a photosensitive film having a latent image of the pattern formed thereon, supplying the rinsing liquid from said rinse supply device to replace the developer, supplying the polymer from said polymer supply device to cover an entire surface of the photosensitive film on the substrate, spinning and drying the substrate with said spin support device, and forming on the substrate a film from which one of the pattern of the photosensitive film and the polymer is removable by dry etching.

11. An apparatus as defined in claim 9, wherein said polymer supply device is arranged to supply the polymer having a lower etching rate in the dry etching than said photosensitive film.

12. An apparatus as defined in claim 10, wherein said polymer supply device is arranged to supply the polymer having a lower etching rate in the dry etching than said photosensitive film.

13. An apparatus as defined in claim 9, wherein said polymer supply device is arranged to supply the polymer based on one of a siloxane, a silicic acid having a Si—O skeleton, and a glass resin.

14. An apparatus as defined in claim 10, wherein said polymer supply device is arranged to supply the polymer based on one of a siloxane, a silicic acid having a Si—O skeleton, and a glass resin.

15. An apparatus as defined in claim 11, wherein said polymer supply device is arranged to supply the polymer based on one of a siloxane, a silicic acid having a Si—O skeleton, and a glass resin.

16. An apparatus as defined in claim 12, wherein said polymer supply device is arranged to supply the polymer based on one of a siloxane, a silicic acid having a Si—O skeleton, and a glass resin.

17. An apparatus as defined in claim 9, wherein said developer supply device, said rinse supply device and said polymer supply device are movable between a supply position above a spin center of said spin support device and a standby position laterally away from said spin support device.

18. An apparatus as defined in claim 10, wherein said developer supply device, said rinse supply device and said polymer supply device are movable between a supply position above a spin center of said spin support device and a standby position laterally away from said spin support device.

19. A pattern forming apparatus for forming a pattern on a substrate, comprising:
a spin support device for spinnably supporting the substrate;
a developer supply device for supplying a developer from above said spin support device;
a rinse supply device for supplying a rinsing liquid from above said spin support device;
a polymer supply device for supplying a polymer soluble in the rinse liquid from above said spin support device;
a dry etching device for ashing one of the film and the polymer; and
a control device for supplying the developer from said developer supply device to the substrate supported by said spin support device and coated with a photosensitive film having a latent image of the pattern formed thereon, supplying the rinsing liquid from said rinse supply device to replace the developer, supplying the polymer from said polymer supply device, while spinning and drying the substrate with said spin support device, to cover an entire surface of the photosensitive film on the substrate, and operating said dry etching device for ashing one of the pattern of the photosensitive film and the polymer.

20. A pattern forming apparatus for forming a predetermined pattern on a substrate, comprising:
a spin support device for spinnably supporting the substrate;
a developer supply device for supplying a developer from above said spin support device;
a rinse supply device for supplying a rinsing liquid from above said spin support device;
a polymer supply device for supplying a polymer soluble in the rinse liquid from above said spin support device;
a dry etching device for ashing one of the film and the polymer; and
a control device for supplying the developer from said developer supply device to the substrate supported by said spin support device and coated with a photosensitive film having a latent image of the pattern formed thereon, supplying the rinsing liquid from said rinse supply device to replace the developer, supplying the polymer from said polymer supply device to cover an entire surface of the photosensitive film on the substrate, spinning and drying the substrate with said spin support device, and operating said dry etching device for ashing one of the pattern of the photosensitive film and the polymer.
